(19) United States
(12) Patent Application Publication
(10) Pub. No.: US 2021/0217663 A1
(43) Pub. Date: Jul. 15, 2021

(54) METHOD FOR SERVERING AN EPITAXIALLY GROWN SEMICONDUCTOR BODY, AND SEMICONDUCTOR CHIP

(71) Applicant: OSRAM OLED GMBH, Regensburg (DE)

(72) Inventors: Lars NÄHLE, Bad Abbach (DE); Sven GERHARD, Alteglofsheim (DE)

(73) Assignee: Osram Oled GmbH, Regensburg (DE)

(21) Appl. No.: 17/053,697

(22) PCT Filed: May 7, 2019
(86) PCT No.: PCT/EP2019/061726

§ 371 Date: Nov. 6, 2020

(30) Foreign Application Priority Data
May 9, 2018 (DE) 10 2018 111 227.0

(51) Int. Cl. H01L 21/78; H01L 21/02; H01L 21/268

(52) U.S. Cl. CPC H01L 21/78; H01L 21/268; H01L 21/02658

(57) ABSTRACT

A method for severing an epitaxially grown semiconductor body is given, in which

a) a growth substrate (2) is provided;

b) at least one trench (20) is produced in a first main surface (2a) of the growth substrate (2) by etching;

c) a semiconductor material is epitaxially deposited on the first main surface (2a) and in the trench (20), wherein a semiconductor body (1) is formed, and the semiconductor body at least partially fills the trench (20); and

d) the semiconductor body and the growth substrate are cut along the main direction of the trench.

Furthermore, a semiconductor chip with a cover surface and side surfaces is specified, in which the side surfaces each have a beveled section that is adjacent to the cover surface and whose surface is created by epitaxy.

A method for severing an epitaxially grown semiconductor body and a semiconductor chip are specified.

One of the tasks to be solved is to specify a particularly efficient method for severing an epitaxially grown semiconductor body, especially for separating such a semiconductor body into semiconductor chips.

A further task to be solved consists among other things of specifying a semiconductor chip which may be operated particularly reliably.

These tasks are solved in particular by a method according to patent claim 1 or by a semiconductor chip with the features of patent claim 14. Further developments of the method and the semiconductor chip are specified in the dependent claims. The disclosure content of the patent claims is hereby included in the description by reference.

In the method for severing an epitaxially grown semiconductor body, a growth substrate is provided in a method step a) and in a method step b) at least one trench is produced in the growth substrate by means of etching from a first main surface of the growth substrate. The trench has a main extension direction.

The growth substrate provided in step a) is intended for the epitaxial deposition of a semiconductor material on its first main surface. For example, the growth substrate is a wafer. In particular, the growth substrate comprises sapphire or gallium nitride (GaN) or consists of sapphire or gallium nitride (GaN).

In step b) a mask is arranged on the first main surface of the growth substrate, which has a window through which the trench is etched. The geometry of the window in combination with the etching process determines the geometry of the trench.

In particular, the mask is formed with a photosensitive resist or as a hard mask. The hard mask comprises for example silicon dioxide, silicon nitride, amorphous carbon, tantalum nitride, titanium nitride, titanium, titanium oxide, platinum or palladium. The trench may be created using a plasma etching process or a wet chemical etching process.

In a method step c), semiconductor material is epitaxially deposited on the first main surface and in the trench, resulting in a semiconductor body that overmoulds the trench and at least partially protrudes into it. In particular, the semiconductor body at least partially fills the trench.

The semiconductor body comprises in particular a semiconductor layer stack, which has, for example, an n-type region, a p-type region and an active region lying between these two regions. The active region is configured to generate or detect electromagnetic radiation.

In a method step d) the semiconductor body and the growth substrate are severed along the main extension direction of the trench, in particular through the trench. In particular, the semiconductor body and the growth substrate are separated into a plurality of semiconductor chips by means of a suitable arrangement of a purity of trenches to each other. In particular, the semiconductor body is severed essentially in its growth direction.

After the severing, each part of the semiconductor body has a part of the n-type layer, a part of the p-type layer and a part of the active region of the semiconductor layer stack.

In step d) the semiconductor body is severed, for example, by means of breaking, whereby the trench defines a predetermined breaking point for the severing. Preferably exclusively the trench defines a predetermined breaking point for the severing. In particular, the semiconductor body is not scribed in the region of the trench, neither by laser, blade, diamond nor any other tool.

In particular, the steps a), b), c) and d) are carried out in the mentioned order.

A method described here is based, among other things, on the fact that in the conventional severing of a semiconductor body to singulate semiconductor chips, the body is cut or scribed, for example, by means of a laser. This produces so-called slag, which adheres to the outer surfaces of the separated semiconductor chips. If the semiconductor body is formed with gallium nitride, for example, the slag includes gallium or gallium oxide and is electrically conductive. The slag may lead to short circuits on the semiconductor chip and thus impair the function of the individual semiconductor chips.

In the method described here, the semiconductor body is severed along a predetermined breaking point, which is defined by etching and overgrowth. Advantageously, no slag is produced during the singulation process.

In an embodiment of the method, in method step b) a mask is placed on the first main surface of the growth substrate and the shape of the trench along the first main surface is defined by the mask. The mask comprises a window through which the trench is etched.

The mask is a structured layer with a window in a region where a trench is etched. After etching the trench, the mask may be removed completely.

In particular, the mask is formed with a material that shows a particularly high selectivity in plasma etching processes or in wet chemical etching processes. For example, the mask is a hard mask formed with amorphous carbon, tantalum nitride, titanium nitride, silicon oxide, silicon nitride. Advantageously, such a mask is essentially not removed during etching of the trench, so the window in the mask is not enlarged during etching. Thus, a particularly deep trench with a particularly small width, i.e. a trench with a particularly large aspect ratio, may be produced.

Alternatively, the mask is formed with a photosensitive resist in which at least one window is created by exposure and development. In step b), for example, the resist mask is removed during etching of the trench in such a way that the window is enlarged. The trench may have a v-shaped cross-section perpendicular to its main extension direction. In the present context, the term “v-shaped” also includes corresponding cross-sections which are not exactly v-shaped but slightly rounded and thus only v-like-shaped. Likewise, the trench may have a rectangular or trapezoidal cross-section perpendicular to its main extension direction. In the present context, the terms “rectangular” and “trapezoidal” also include corresponding cross-sections which are not exactly rectangular or trapezoidal, but have slightly rounded corners and are thus only rectangular-like or trapezoidal-like in shape. In principle, any cross-sectional shape of the trench is suitable.

According to one embodiment, after method step c) the semiconductor body comprises a depression on a front side facing away from the growth substrate, wherein the depression overlaps the trench in the growth direction of the semiconductor body and has a v-shaped cross-section perpendicular to the main extension direction of the trench. With regard to “v-shaped”, the above mentioned analogously applies to the trench here.

In particular, the depression has a similar depth as the associated trench. In particular, the depth of the depression is less than the depth of the trench.

In an embodiment of the method, the depth of the depression is greater than the thickness of the semiconductor body and the depression extends into the trench.

In one embodiment of the method, a recess in the semiconductor body is formed in the trench in method step c). The semiconductor body thus comprises a recess after method step c). This is caused by the fact that the growth process of the semiconductor body is conducted in such a way that when the semiconductor body grows together above the trench during the growth of semiconductor material, the trench is not yet completely filled with semiconductor material.

For example, by means of the geometry of the cross-section of the trench, it may be determined whether or not the recess is formed when the semiconductor body is grown. For example, a trench, in which a recess is formed during the growth of the semiconductor body, has a cross-section with a greater depth than width. For example, the cross-section of the trench has an aspect ratio of at least 1:1, preferably at least 10:1.

In an embodiment, the recess is limited on all sides by the material of the semiconductor body. In other words, the recess is entirely in semiconductor body material. The recess may be filled with a gas.

Advantageously, the mechanical stability of the semiconductor body, especially of the compound of semiconductor body and growth substrate, is reduced along the recess, so that the recess defines a predetermined breaking point of the compound of semiconductor body and growth substrate.

In one embodiment, an absorber structure is arranged in the trench. In particular, the absorber structure is located in the recess of the semiconductor body. The absorber structure is formed with an absorber material, and the absorber material has a higher absorption capacity for electromagnetic radiation in a predetermined electromagnetic wavelength range than the material of the semiconductor body and/or the growth substrate. For example, the absorber material completely fills the trench or the recess described above. In method step d) the absorber structure is heated by irradiation and the compound of the semiconductor body and the growth substrate is severed along the absorber structure.

The absorber structure is irradiated with electromagnetic radiation of a wavelength range in which the absorption capacity of the absorber material is higher than the absorption capacity of the material of the growth substrate and/or the material of the semiconductor body. Due to the higher absorption of the electromagnetic radiation in the absorber structure, the absorber structure is heated more than the semiconductor body and the growth substrate. Thus, the absorber structure expands more strongly than the growth substrate and the semiconductor body, so that mechanical stresses are created along the absorber structure in the growth substrate and in the semiconductor body. The mechanical stresses can already cause the semiconductor body to be severed along the absorber material.

Advantageously, the increased absorptive capacity of the absorber material allows a selective heating of the absorber structure by means of electromagnetic radiation, whereby the semiconductor body is severed along the absorber structure by means of thermomechanical stresses. In particular, the absorber material may be a dielectric or a metal. For example, the absorber material may be silicon nitride (SiN), titanium (Ti), titanium tungsten nitride (TiWN), gold (Au), titanium nitride (TiN) or benzocyclobutene (BCB).

According to at least one embodiment, in method step d) the absorber structure and regions of the semiconductor body and the growth substrate adjacent to the absorber structure are irradiated. For example, the compound of semiconductor body and growth substrate is irradiated flat through the front side of the semiconductor body facing away from the growth substrate and/or through the back side of the growth substrate facing away from the semiconductor body, without focusing the electromagnetic radiation specifically on the absorber structure. Alternatively, the front side of the semiconductor body or the back side of the growth substrate including at least a part of the absorber structure can be irradiated locally by laser radiation.

For example, the absorber structure along the cross-sectional area of the trench has a maximum width of 15 μm, preferably 5 μm. In particular, the intensity of the electromagnetic radiation for heating the absorber structure in method step d) is selected in such a way that the semiconductor body and/or the growth substrate are not melted.

For example, the material of the semiconductor body and/or the growth substrate is essentially transparent to the electromagnetic radiation used. By means of the absorber structure, the semiconductor body is precisely severed along the absorber structure, even if regions outside the absorber structure are also irradiated. A separation region of the compound of semiconductor body and growth substrate is thus advantageously not determined by the beam geometry of the electromagnetic radiation, but by the geometry of the absorber structure.

According to one embodiment, the absorber structure projects beyond the semiconductor body in the growth direction. This has the advantage that irradiation of the absorber structure is technically simplified.

According to at least one embodiment of the method, the absorber structure completely covers a bottom surface of the trench. In particular, the absorber structure completely covers the bottom surface of the trench before method step d).

In another embodiment, the absorber structure is completely covered with material of the semiconductor body on a side facing away from the growth substrate. Thus, a predetermined breaking point may be defined on a side of the semiconductor body facing the growth substrate.

According to another embodiment, an expansion structure is arranged in the recess, wherein the expansion structure is formed with an expansion material, and the expansion material has a greater coefficient of thermal expansion than the material of the semiconductor body and/or the growth substrate. According to this embodiment, in step d) the temperature of the compound of the semiconductor body, the growth substrate and the expansion structure is changed and the compound with the semiconductor body and the growth substrate is severed along the expansion structure. In particular, the entire compound is heated in such a way that the temperature of the growth substrate, the semiconductor body and the expansion structure increases essentially homogeneously. When severing by means of the expansion structure, temperature gradients in the semiconductor body and/or growth substrate may be counteracted. Advantageously, mechanical tensions are induced by the temperature change mainly in regions adjacent to the expansion structure, so that a targeted severing of the semiconductor body along the expansion structure takes place.

According to at least one embodiment, a separating element is arranged in the recess, which is configured to exert a separating force on the semiconductor body and/or the growth substrate by means of thermal expansion. In method step d) the semiconductor body and the growth substrate are severed by means of the separating force. In particular, in method step d) the separating element expands more strongly than the material of the semiconductor body and/or the growth substrate surrounding the separating element due to a temperature change. The greater thermal expansion can be achieved in step d) by selectively changing the temperature of the separating element.

Alternatively or additionally, the separating element may be formed with a material having a coefficient of thermal expansion which is different from the material of the semiconductor body and/or the growth substrate surrounding the separating element. For example, the coefficient of thermal expansion of the separating element differs from the coefficient of thermal expansion of the semiconductor body and/or the growth substrate at least by a factor of 1.5, preferably at least by a factor of 2. In particular, the separating element is formed by the absorber structure and/or the expansion structure. For example, the semiconductor chip has the material of the separating element on side surfaces. According to one embodiment of the method, a plurality of trenches is produced in the growth substrate in method step b). The trenches extend with their respective main extension direction along grid lines of a virtual periodic grid lying in the first main surface, along which the semiconductor body is singulated into semiconductor chips in step d). For example, several separate trenches are arranged along a grid line. The trenches are created simultaneously in step b).

In the preceding embodiment, the plurality of trenches includes, for example, first trenches and second trenches. The main extension direction of first trenches is transverse, in particular perpendicular to the main extension direction of second trenches. First trenches and second trenches do not cross each other. For example, first trenches run parallel to each other and second trenches run parallel to each other. For example, grid lines along which first trenches extend are free from second trenches and/or grid lines along which second trenches extend are free from first trenches.

A semiconductor chip is also specified. In particular, the semiconductor chip is manufactured with a method described here. This means that all features disclosed for the method are also disclosed for the semiconductor chip and vice versa.

For example, the semiconductor chip is an optoelectronic semiconductor chip, in particular a semiconductor laser diode. For example, the semiconductor chip is based on the gallium nitride compound semiconductor material system.

The semiconductor chip comprises a cover surface and a plurality of side surfaces. At least some of the side surfaces, especially all side surfaces of the semiconductor chip each have at least one beveled section. The beveled section is adjacent to the cover surface of the semiconductor chip and is part of the front surface of the epitaxially grown semiconductor body. The surface of the beveled section is therefore created by epitaxy, i.e. it is not created by a material removal process on a previous epitaxially produced material layer.

The beveled sections are thus each a part of a depression, which was formed in the front side of the semiconductor body during the epitaxy.

The remaining sections of the side surfaces are at least partly surfaces that were created by severing the compound of semiconductor body and growth substrate by one of the methods described above. The semiconductor chip is advantageously free of melting slag, which would have been produced, for example, during separation by laser radiation.

According to one embodiment, the side surfaces show a material residue of an absorber structure and/or an expansion structure. In particular, the side surfaces are at least partially formed with the material of the absorber structure or the expansion structure.

For example, the beveled section has an angle of 60° and/or 120° relative to the growth direction of the semiconductor body. In particular, the side surface in the beveled section is epitaxially formed so that it is particularly smooth.

Advantageous embodiments and developments of the method for severing an epitaxially grown semiconductor body and the semiconductor chip will become apparent from the exemplary embodiments described below in association with the figures.

In the figures:

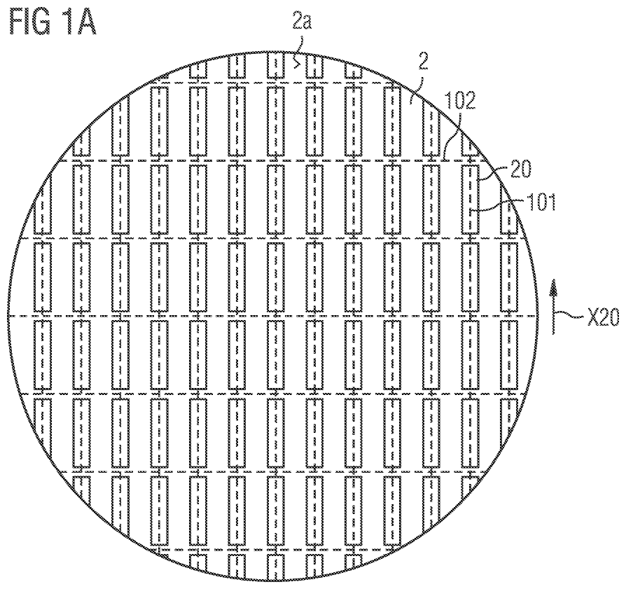

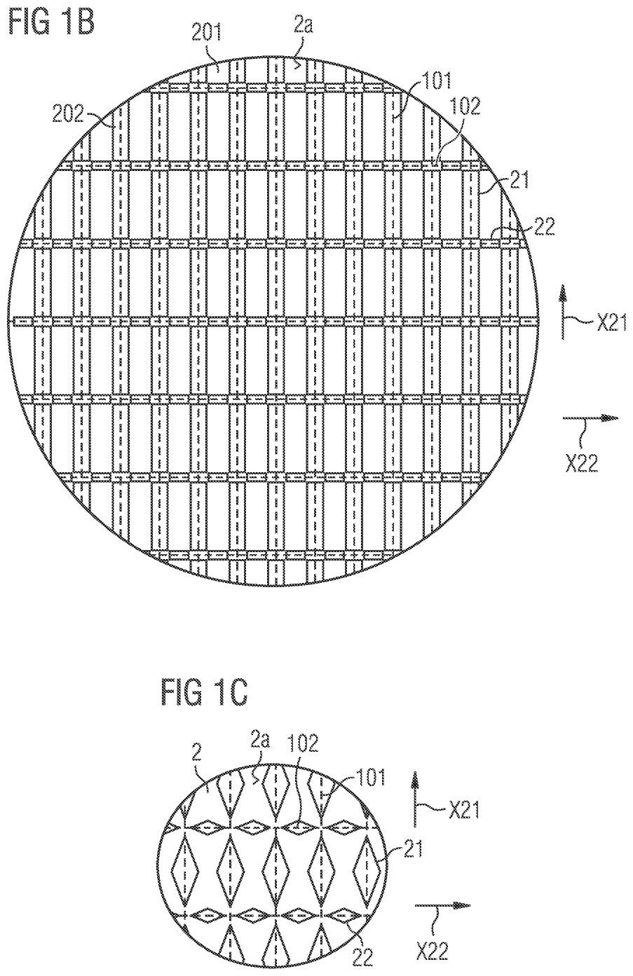

FIGS. 1A, 1B, and 1C, schematic representations of plan views of the first main surface of a growth substrate used in a method for severing a semiconductor body according to an exemplary embodiment;

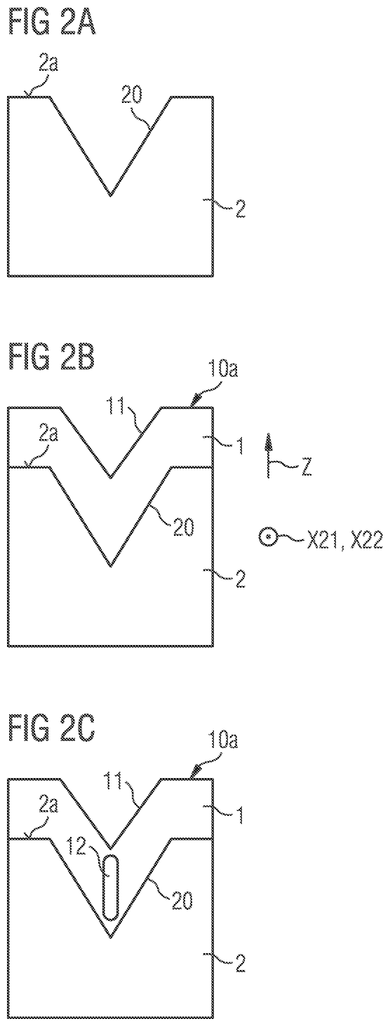

FIGS. 2A, 2B, 2C, 3A, 3B, 3C, 3D, 4A, 4B, 5, 6 and 7, schematic representations of sectional views of embodiments of a growth substrate and a semiconductor body at different stages of a method described herein;

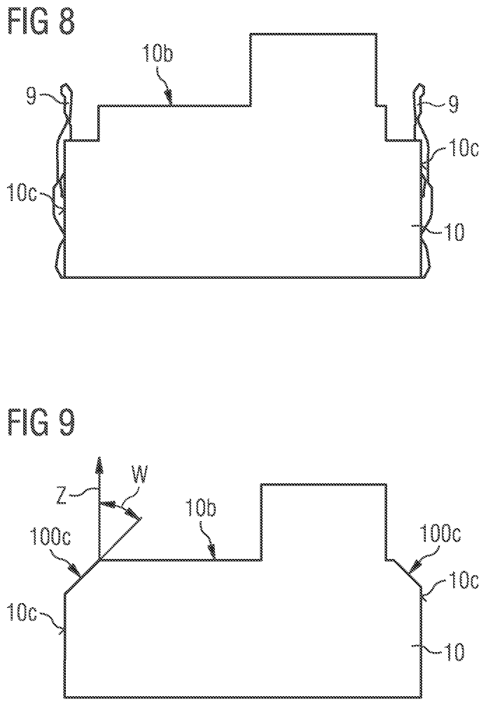

FIG. 8 a schematic representation of a side view of an example of a semiconductor chip; and

FIG. 9 a schematic representation of a side view of an exemplary embodiment of a semiconductor chip.

In the exemplary embodiments and figures, similar or similarly acting constituent parts are provided with the same reference symbols. The elements illustrated in the figures and their size relationships among one another should not be regarded as true to scale. Rather, individual elements may be represented with an exaggerated size for the sake of better representability and/or for the sake of better understanding.

FIG. 1A shows a schematic plan view of a first main surface 2a of a growth substrate 2, which has been provided in a method step a) of one of the above described methods and has been provided with a plurality of trenches 20, whose main extension directions X20 are parallel to each other, in a method step b) of one of the above described methods. The trenches 20 have been produced by etching, in particular by plasma etching, using a mask (for example as described above) and have a v-shaped or preferably a rectangular or trapezoidal cross-section perpendicular to the main extension direction X20. They lie on parallel first grid lines 101 of a regularly orthogonal virtual grid lying in the first main surface 2a of the growth substrate 2 and do not intersect second grid lines 102, which are perpendicular to the main extension direction X20. The trenches 20 are thus periodically arranged along the first main surface 2a at regular intervals to each other.

In method step b), a mask 201 is arranged on the first main surface 2a of the growth substrate 2. The mask 201 has a window 203 through which the trench is etched.

The growth substrate 2 of FIG. 1B differs from that of FIG. 1A in that first trenches 21 and second trenches 22 are formed in it, e.g. by means of one of the above mentioned etching processes.

The main extension direction X21 of first trenches 21 is perpendicular to the main extension direction X22 of second trenches 22. The second trenches 22 expand along the second grid lines 102 of the regular orthogonal virtual grid located in the first main surface 2a of the growth substrate 2. The first trenches 21 and the second trenches 22 do not cross each other.

The distance between parallel trenches 21, 22 is for example between 10 μm and 2000 μm inclusive, preferably between 100 μm and 200 μm inclusive. A width of the trenches 21, 22 perpendicular to their main extension direction X21, X22 is between 1 μm and 50 μm inclusive, preferably between 1 μm and 20 μm inclusive.

The growth substrate 2 of FIG. 1C differs from the growth substrate 2 of FIG. 1B in that the first trenches 21 and the second trenches 22 do not have a rectangular contour as seen in plan view of the growth substrate 2, but each have a rhombic contour or especially a polygonal contour.

FIG. 2A shows a schematic sectional view of an exemplary embodiment of a growth substrate 2 in which a trench 20 is arranged. In a method step b), the trench is inserted into the growth substrate 2 by etching from the first main surface 2a of the growth substrate 2. In particular, the trench is made using a hard mask, which was completely removed after etching.

In a method step c), as schematically illustrated in FIG. 2B, the semiconductor body 1 is epitaxially deposited on the first main surface 2a and in the region of the trench 20, wherein the semiconductor body 1 fills the trench 20. In an alternative embodiment, trench 20 is only partially filled by the semiconductor body 1. The inner surfaces of the trench 20 are completely covered with the material of the semiconductor body 1.

The semiconductor body 1 is in direct contact with the growth substrate 2 at the first main surface 2a and in the region of the trench 20. The semiconductor body 1 is grown along a growth direction Z on the growth substrate 2. At a front side 10a of the semiconductor body 1, which faces away from the growth substrate 2, the semiconductor body 1 comprises a depression 11, which overlaps with the trench 20 along the growth direction Z. Perpendicular to the main directions X21, X22 of the trench 20, the depression 11 has a v-shaped cross-section. For example, depression 11 defines a predetermined breaking point in the semiconductor body 1, along which the growth substrate 2 and semiconductor body 1 are separated by breaking in method step d).

FIG. 2C shows an alternative exemplary embodiment to FIG. 2B of a compound of a growth substrate 2 and a semiconductor body 1, in which a recess 12 has been formed in the region of the trench 20 in semiconductor body 1 in addition to the depression 11. The recess 12 is bounded on all sides by material of the semiconductor body 1. In particular, according to an alternative exemplary embodiment, the recess 12 may be partially bounded by the growth substrate 2. For example, the recess 12 is filled with gas. When severing the compound of growth substrate 2 and semiconductor body 1 in method step d), the semiconductor body is severed along the recess 12 and the depression 11.

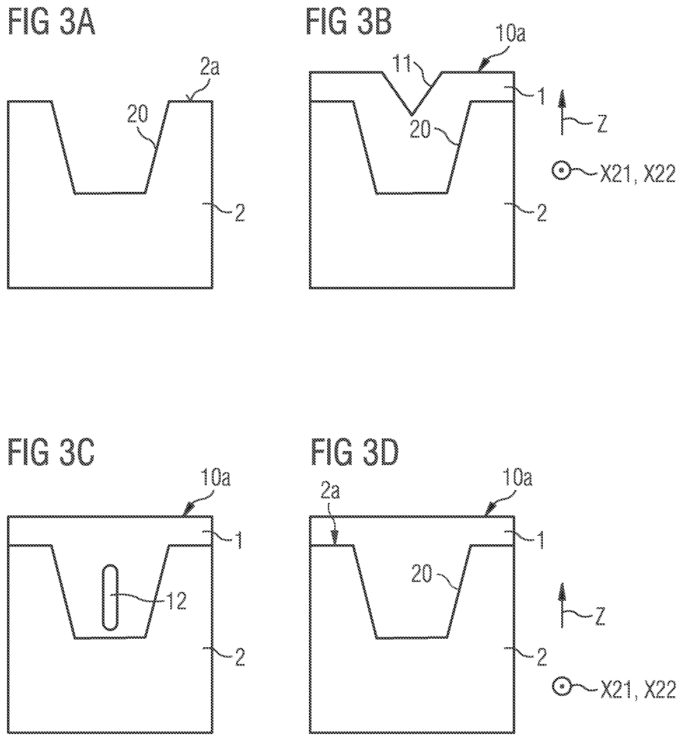

FIG. 3A shows a schematic sectional view of another exemplary embodiment of a growth substrate 2 with a trench 20. The trench 20 has a trapezoidal cross-section perpendicular to its main extension direction. The geometry of trench 20 was determined, for example, by a resist mask and the trench 20 was etched by an anisotropic etching process. The anisotropic etching process in combination with a resist mask leads to a trapezoidal cross-sectional profile of trench 20.

FIG. 3B shows a schematic cross-sectional view after the corresponding steps a), b) and c). In the region of the trench 20 and at the first main surface 2a of the growth substrate 2 a semiconductor body 1 is grown in a growth direction Z. In the region of the trench 20, a depression 11 has been created on the front side 10a of semiconductor body 1. The depression 11 has a v-shaped cross-section. Advantageously the semiconductor body 1 can be easily severed along the depression 11.

FIG. 3C shows another embodiment where the front side 10a of the semiconductor body 1 is planar. During the growth of semiconductor body 1, a recess 12 was formed in it, which is surrounded on all sides by the material of semiconductor body 1. The recess 12 is filled with gas. Advantageously, the recess 12 defines a predetermined breaking point of the semiconductor body 1, along which the semiconductor body 1 may be severed in a particularly simplified way. In addition, the semiconductor body 1 with a flat front side 10a may be processed in a particularly simplified way.

The FIG. 3D shows a further embodiment. The semiconductor body 1 has a planar front side 10a and the trench 20 is completely filled with the material of the semiconductor body 1. In particular, the semiconductor body 1 does not have a recess 12 in the region of the trench 20.

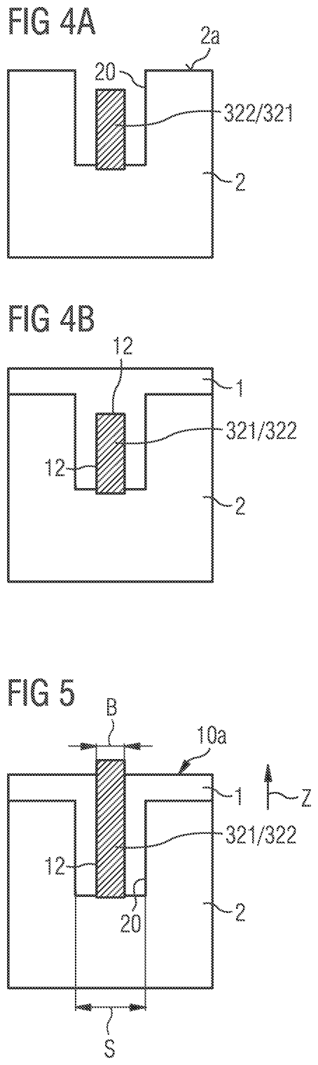

FIG. 4A shows an embodiment of a growth substrate 2 with a rectangular trench 20. Trench 20 contains an absorber structure 321. Alternatively, an expansion structure 322 may be arranged in trench 20 instead of the absorber structure 321. Exemplary materials for the absorber structure or the expansion structure and their functionalities are given above.

In method step c), as illustrated in FIG. 4B, the semiconductor body 1 is epitaxially deposited, wherein the trench 20 is filled with the material of semiconductor body 1. In particular, the absorber structure 321 or the expansion structure 322 is completely covered by the semiconductor body 1. Consequently, the semiconductor body 1 has a recess 12 in which the absorber structure 321 and the expansion structure 322 are located. In particular, the recess 12 is completely filled with the absorber material of absorber structure 321 or the expansion material of expansion structure 322.

The exemplary embodiment of FIG. 5 differs from that of FIG. 4B in that the absorber structure 321 or the expansion structure 322 protrudes beyond the front side 10a of the semiconductor body 1. In particular, the width of the absorber structure 321 or the expansion structure 322 is B. The width B, for example, is smaller than a width S of the trench 20. In particular, the width B of absorber structure 321 and expansion structure 322 is between 1 μm and 5 μm.

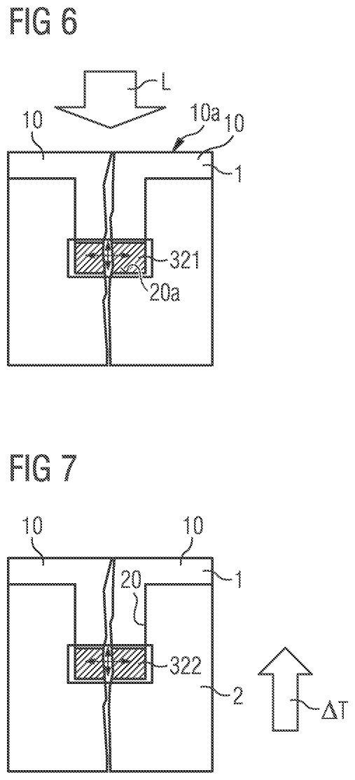

FIG. 6 shows a schematic sectional view of a semiconductor body 1, which is severed in a method step d) according to an exemplary embodiment of the method described here. In this method step the semiconductor body 1 and the growth substrate 2 are severed along the trench 20. The absorber material of the absorber structure 321 has a higher absorption capacity for electromagnetic radiation L in a given wavelength range than the material of semiconductor body 1 and/or growth substrate 2. In method step d), the absorber structure 321 is selectively heated by irradiation. The absorber structure 321 expands more strongly than the material of the growth substrate 2 and/or the semiconductor body 1 surrounding the absorber material 321. As a result, the absorber material generates mechanical stresses in the semiconductor body 1 and in the growth substrate by means of which the semiconductor body 1 is severed along the absorber structure 321.

FIG. 7 shows a schematic sectional view of a semiconductor body 1, which is severed along the trench 20 in method step d). In this exemplary embodiment the recess 12 is completely filled with the expansion structure 322. In particular, the trench 20 has a bottom surface 20a, which is completely covered with the expansion material of expansion structure 322. The expansion structure 322 has a higher coefficient of thermal expansion than the growth substrate 2 and the semiconductor body 1. In method step d) the temperature T of the compound of the semiconductor body 1, the growth substrate 2 and the expansion structure 322 is increased. The expansion material of the expansion structure 322 expands more than the semiconductor body 1 and the growth substrate 2, thus creating mechanical stresses in the compound which severs the semiconductor body along the expansion structure 322.

FIG. 8 shows a schematic sectional view of a semiconductor chip 10, which was singluated by a conventional method, in which the semiconductor body was at least partially cut by laser radiation. The semiconductor chip 10 comprises a cover surface 10b and a side surface 10c adjacent to the cover surface 10b. Slag 9 is formed on at least one of the side surfaces 10c. The slag 9 is formed with gallium and/or gallium oxide, for example. In particular, the slag 9 may come into contact with electrically conductive structures during assembly of the semiconductor chip and thus cause a short circuit of the semiconductor chip 10.

FIG. 9 shows a schematic sectional view of a semiconductor chip 10 according to an embodiment. In particular, the semiconductor chip 10 is a laser diode. In particular, the semiconductor chip is manufactured using the method described here for severing a semiconductor body. The semiconductor chip 10 has a cover surface 10b, which borders on side surfaces 10c. The side surfaces 10c each have a beveled section 100c, wherein the beveled section 100c adjoins the cover surface 10b. The beveled section 100c is generated by epitaxy, i.e., it is not created by a process where material of a previously epitaxially generated layer is removed. Depending on the method used, the side surface 10c may show traces of absorber material and/or expansion material according to one of the embodiments described above. The beveled section 100c has an angle W relative to the growth direction Z of the semiconductor body 1. The angle W is determined, for example, by the crystalline structure of semiconductor body 1 and is, for example, 60° or 120°.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

This patent application claims the priority of German patent application DE 10 2018 111 227.0, the disclosure content of which is hereby incorporated by reference.

### REFERENCE NUMERALS

1 semiconductor body

2 growth substrate

2a first main surface

9 slag

10 semiconductor chip

10a front side of the semiconductor body

10b cover surface

10c side surface

11 depression

12 recess

20 trench

20a bottom surface of the trench

21 first trench

22 second trench

100c beveled section

101 grid line

102 grid line

201 mask

203 window

321 absorber structure

322 expansion structure

B width

L electromagnetic radiation

S width of the trench

T temperature

W angle

X20 main extension direction of the trench

X21 main extension direction of the first trench

X22 main extension direction of the second trench

Z growth direction

1. A method for severing an epitaxially grown semiconductor body, wherein
a) a growth substrate is provided;
b) at least one trench having a main extension direction is produced in the growth substrate by etching from a first main surface of the growth substrate;
c) a semiconductor material is epitaxially deposited on the first main surface and in the trench, wherein a semiconductor body is formed which at least partially fills the trench; and
d) the semiconductor body and the growth substrate are severed through the trench along the main extension direction.

2. The method according to claim 1, wherein exclusively the trench defines a predetermined breaking point for the severing.

3. The method according to claim 1, wherein
in method step b) a mask is arranged on the first main surface of the growth substrate), and
the mask has a window through which the trench is etched.

4. The method according to claim 1, wherein
after method step c) the semiconductor body has a depression on a front side facing away from the growth substrate, and
the depression overlaps with the trench in growth direction of the semiconductor body and has a v-shaped cross-section perpendicular to the main extension direction of the trench.

5. The method according to claim 1, wherein
after method step c) the semiconductor body has a recess in the trench.

6. The method according to claim 5 4, wherein the recess is limited on all sides by the material of the semiconductor body.

7. The method according to claim 4, wherein
an absorber structure is arranged in the recess,
the absorber structure is formed with an absorber material having a higher absorption capacity for electromagnetic radiation in a predetermined wavelength range than the material of the semiconductor body and/or the growth substrate,
in method step d) the absorber structure is heated by irradiation.

8. The method according to claim 7, wherein the absorber structure and regions of the semiconductor body and the growth substrate adjacent to the absorber structure are irradiated.

9. The method according to claim 7, wherein the absorber structure projects beyond the semiconductor body in a growth direction of the semiconductor body.

10. The method according to claim 7, wherein
the absorber structure completely covers a bottom surface of the trench.

11. The method according to claim 4, wherein
an expansion structure is arranged in the recess, wherein
the expansion structure is formed with an expansion material, wherein the expansion material has a larger coefficient of thermal expansion than the material of the semiconductor body and/or the growth substrate,
in method step d) the temperature of the compound comprising the semiconductor body, the growth substrate and the expansion structure is changed, and
the compound with the semiconductor body and the growth substrate is severed along the expansion structure.

12. The method according to claim 1, wherein
in method step b), a plurality of trenches is produced in the growth substrate, the main extension directions of these trenches extend along grid lines of a virtual periodic grid, which is located in the first main surface of the growth substrate.

13. The method according to claim 12, wherein
the plurality of trenches comprises first trenches and second trenches,
the main extension direction of first trenches is transverse to the main extension direction of second trenches, and
first trenches and second trenches do not cross each other.

14. A semiconductor chip with a cover surface and a plurality of side surfaces, wherein
the side surfaces each have a beveled section, wherein
the beveled section is adjacent to the cover surface, and
the surface of the beveled section is created by epitaxy.

15. The semiconductor chip according to claim 14, in which the side surfaces comprise absorber material and/or expansion material.

16. A method for severing an epitaxially grown semiconductor body comprising
a) providing a growth substrate;
b) producing at least one trench having a main extension direction in the growth substrate by etching from a first main surface of the growth substrate;
c) epitaxially depositing a semiconductor material on the first main surface and in the trench, wherein a semiconductor body is formed which at least partially fills the trench; and
d) severing the semiconductor body and the growth substrate through the trench along the main extension direction, wherein
after method step c) the semiconductor body has a recess in the trench,
a separating element is arranged in the recess,
the separating element is configured to exert a separating force on the semiconductor body and/or growth substrate by thermal expansion, and
in method step d) the semiconductor body and the growth substrate are severed by the separating force.
